(19) United States
(12) Patent Application Publication
(10) Pub. No.: US 2007/0215572 A1
(43) Pub. Date: Sep. 20, 2007

(54) SUBSTRATE PROCESSING METHOD AND SUBSTRATE PROCESSING APPARATUS

(76) Inventor: Kimitsugu Saito, Kyoto (JP)

Correspondence Address: OSTROLENK FABER GERB & SOFFEN, 1180 AVENUE OF THE AMERICAS, NEW YORK, NY, 100368403, US

(21) Appl. No.: 11/687,238

(22) Filed: Mar. 16, 2007

(30) Foreign Application Priority Data
Mar. 20, 2006 (JP) 2006-076006

(51) Int. Cl. B44C 1/22; C23C 14/00; H01L 21/306

(52) U.S. Cl. 216/37; 118/50; 156/345.11

(57) ABSTRACT

A processing fluid is prepared by mixing purified water and methanol as a solvent with SCCO2, and the processing fluid is brought into contact with a surface of a substrate so as to form oxide film on the surface of the substrate. In this processing fluid, SCCO2 functions as a carrier medium while —OH functional group (hydroxyl group) disperse in the SCCO2 as active chemical species. Such the highly motile and highly concentrated SCCO2 is used as a carrier medium, while the active chemical species are mixed with carrier medium. Because of this, excessive presence of active chemical species is prevented in the atmosphere in contact with the surface of the substrate. The active chemical species demonstrates superior diffusiveness, and moreover, even a small amount of solvent contains large amount of active chemical species. Therefore, the fresh active chemical species are constantly supplied to the surface of the substrate, reacting excellently with the surface of the substrate, thereby forming oxide film.

### CROSS REFERENCE TO RELATED APPLICATION

The disclosure of Japanese Patent Application No. 2006-76006 filed Mar. 20, 2006 including specification, drawings and claims is incorporated herein by reference in its entirety.

### BACKGROUND OF THE INVENTION

1. Field of the Invention

The present invention relates to a substrate processing method for forming an oxide film on a surface of a substrate. A substrate herein includes various substrates such as for example a semiconductor wafer, a glass substrate for photo-mask, a glass substrate for liquid crystal display, a glass substrate for plasma display, a substrate for optical disk, etc. (hereinafter, simply referred to as “substrate”).

2. Description of the Related Art

As for a substrate processing method, the methods, which are described, for example, in JP-A-2000-357686 and JP-A-2003-213425 have conventionally been proposed. According to the method described in the JP-A-2000-357686, an oxide film is formed onto a surface of a silicon substrate as follows. At first, the silicon substrate is placed on a sample board, which is installed within a vessel. The sample board is provided with a heating mechanism and is capable of heating a substrate. Next, while the vessel is filled with water that is at supercritical state, a silicon substrate is heated by the heating mechanism to 600 degrees Celsius. As a result, an approximately 10 nm-thick silicon oxide film is formed onto the surface of the silicon substrate.

Further, according to the method described in the JP-A-2003-213425, while a substrate is retained within a film-forming chamber, a raw material fluid is sprayed on the substrate to form a film. The raw material fluid, which is used herein, is a mixture of condensed polymer consisting of the elements constituting oxide, carbon dioxide at supercritical state and alcohol. A raw material fluid is sprayed to the substrate to form a think film on the surface of the substrate. Subsequently, the substrate is heated to crystallize the thin film formed thereon to obtain an oxidize film.

### SUMMARY OF THE INVENTION

According to the substrate processing method described in the JP-A-2000-357686, the vessel is filled with the water, which is instrumental to oxidizing effect and is turned to the supercritical state. In order to achieve the supercritical state of the water, relatively high temperature and pressure setting are required. Further, the surface of the substrate is rich with the supercritical water, which is a substance controlling oxidizing effect. Therefore, following problems occur from processing controllability standpoint. Specifically, as described above, the method described in the JP-A-2000-357686 is capable of producing the 10 nm-thick film. In the method, the atmosphere, which is in contact with the surface of the substrate, is rich with activated chemical species which causes oxidization of the surface of the substrate (hereinafter simply called as “active chemical species”). This, together with relatively high temperature, makes it difficult to control thickness of the film on the contrary. Particularly, there recently has been a growing demand for forming a super thin film as a base for a high-permittivity film, for example, an oxide film with its thickness below 1 nm, on the surface of the substrate. However, this demand has not been sufficiently delivered by the conventional method. Also, in the case that impurities find their way into the substrate, relatively high processing temperature in the atmosphere may cause the impurities to react to the substrate or spread inside the substrate to become a factor for lower production yield.

Further, according to the substrate processing method indicated in the JP-A-2003-213425, the oxide film is formed by a vapor deposition method. Hence, its film quality and surface uniformity is inferior to the method wherein the surface of the substrate is oxidized by the active chemical species. Further, similar to the aforementioned substrate processing method, the need for processing through high temperature heating after forming a film may cause problems such as impurities reacting to the substrate, impurities spreading inside the substrate, etc. Moreover, since this substrate processing method requires a film forming process and a heating process to be conducted sequentially, there has been a considerable amount of waste in time and cost.

It is an object of the present invention to provide the substrate processing method, which is capable of forming a high quality and super-thin oxide film on the substrate.

According to the present invention, a processing fluid is prepared by means of mixing a solvent with high-pressure carbon dioxide. The solvent is a chemical compound having an —OH function group. In a first aspect of the present invention, the processing fluid is supplied to a substrate having a dry surface, so that an oxide film is formed onto the dry surface. In a second aspect of the present invention, the processing fluid is supplied to a substrate having a dry surface onto which an oxide film is formed, so that film quality of the oxide film is improved as well as the oxide film is promoted incremental growth.

In the invention arranged as described above, the processing fluid is prepared by mixing the chemical compound having the —OH functional group as a solvent with high-pressure carbon dioxide. Therefore, active chemical species, which causes oxidation triggered by the —OH functional group (hydroxyl), is developed in the high-pressure carbon dioxide in the processing fluid. Further, since kinetic energy of the high-pressure carbon dioxide is as great as that of gas, the high-pressure carbon dioxide, which is chemically inactive against the substrate, acts as a medium for carrying the active chemical species. Therefore, the —OH functional group is dispersed as the active chemical species in the high-pressure carbon dioxide to cause oxidation of the surface of the substrate and to improve film quality. Because of this, excessive presence of the active chemical species on the surface of the substrate is prevented, thereby preventing excessive forming of oxide film.

Further, the high-pressure carbon oxide is highly motile, while the active chemical species are present in the high-pressure carbon dioxide with great diffusiveness. Moreover, with a concentration of the high-pressure carbon dioxide being as high as that of liquid, the high-pressure carbon dioxide provided with even a small amount of the solvent can contain much greater amount of the active chemical species than ordinary gas such as moisture vapor. Therefore, freshly active chemical species are constantly supplied to the entire surface of the substrate, reacting nicely with the surface of the substrate to form an oxide film. Further, according to the invention, which is arranged in forgoing manner, thickness of the oxide film can be adjusted accurately by controlling process conditions for forming an oxide film on the surface of the substrate.

A high-pressure carbon oxide referred to in relation to the invention is a fluid whose pressure is equal to or higher than 1 MPa. Preferable high-pressure carbon oxide is such a fluid which is dense and highly soluble and exhibit low viscosity and high diffusive properties. More preferable high-pressure carbon oxide is a supercritical or subcritical fluid. Carbon dioxide may be heated up to 31 degrees Celsius and pressurized up to 7.4 MPa or beyond to be transformed into a supercritical fluid. In the present invention, it is more preferable to use the high-pressure carbon oxide at 8 through 30 MPa.

As for temperature, it is desirable that processing is performed between 40 to 150 degrees Celsius, while it is even more preferable to be between 60 to 90 degrees Celsius. Since the present invention uses the high-pressure carbon dioxide to form an oxide film and improve film quality, the temperature requirement for the substrate processing is around 31 degrees Celsius, so as to transform the carbon dioxide into supercritical fluid, which is significantly lower than that of conventional technology. Therefore, the problems such as impurities reacting to the substrate as well as the problems such as impurities dispersing inside the substrate can be prevented completely, ensuring the forming of oxide film without lowering productivity yield.

As described above, according to this invention, since the processing fluid is prepared by mixing chemical compound provided with the —OH functional group with the high-pressure carbon dioxide, and since the processing fluid is used 1) to newly form an oxide film on the surface of the substrate and 2) to cause incremental growth of an oxide film while improving quality of the oxide film that is already formed, superior quality of the oxide film is formed. Moreover, this invention uses the processing fluid wherein the active chemical species is dispersed in the high-pressure carbon dioxide, which combines superior motility equaling to that of gas and excellent concentration equaling to that of a liquid, to form and grow an oxide film and improve quality of the oxide film. Therefore, a super-thin oxide film can be formed onto the substrate with uniformity.

The above and further objects and novel features of the invention will more fully appear from the following detailed description when the same is read in connection with the accompanying drawing. It is to be expressly understood, however, that the drawing is for purpose of illustration only and is not intended as a definition of the limits of the invention.

### BRIEF DESCRIPTION OF THE DRAWINGS

FIG. 1 is a drawing which shows a substrate processing apparatus which is able to implement a first embodiment of a substrate processing method according to the invention;

FIG. 2 is a block diagram which shows an electric structure for controlling the substrate processing apparatus of FIG. 1;

FIG. 3 is a flow chart which shows the first embodiment of the substrate processing method according to the invention;

FIG. 4 is a diagram showing a substrate processing system, capable of performing a second embodiment;

FIG. 5 is a flow chart showing the substrate processing method of the second embodiment related to this invention;

FIG. 6 is a diagram showing a substrate processing system, capable of performing a third embodiment;

FIG. 7 is a flowchart showing the third embodiment of the substrate processing method related to this invention;

FIG. 8 is a diagram showing a substrate processing system, capable of performing a fourth embodiment;

FIG. 9 is a flowchart showing the fourth embodiment of the substrate processing method;

FIG. 10 is a diagram showing a substrate processing system, capable of performing a fifth embodiment;

FIG. 11 is a flowchart showing the fifth embodiment of the substrate processing method related to this invention;

FIG. 12 is a diagram showing a substrate processing system, capable of performing a sixth embodiment;

FIG. 13 is a chart showing the film forming apparatus installed in the substrate processing system of FIG. 12;

FIG. 14 is a diagram showing a substrate processing system, capable of performing a seventh embodiment; and

FIGS. 15 and 16 are flow charts showing the seventh embodiment of the substrate processing method related to this invention.

### DETAILED DESCRIPTION OF THE PREFERRED EMBODIMENTS

### First Embodiment

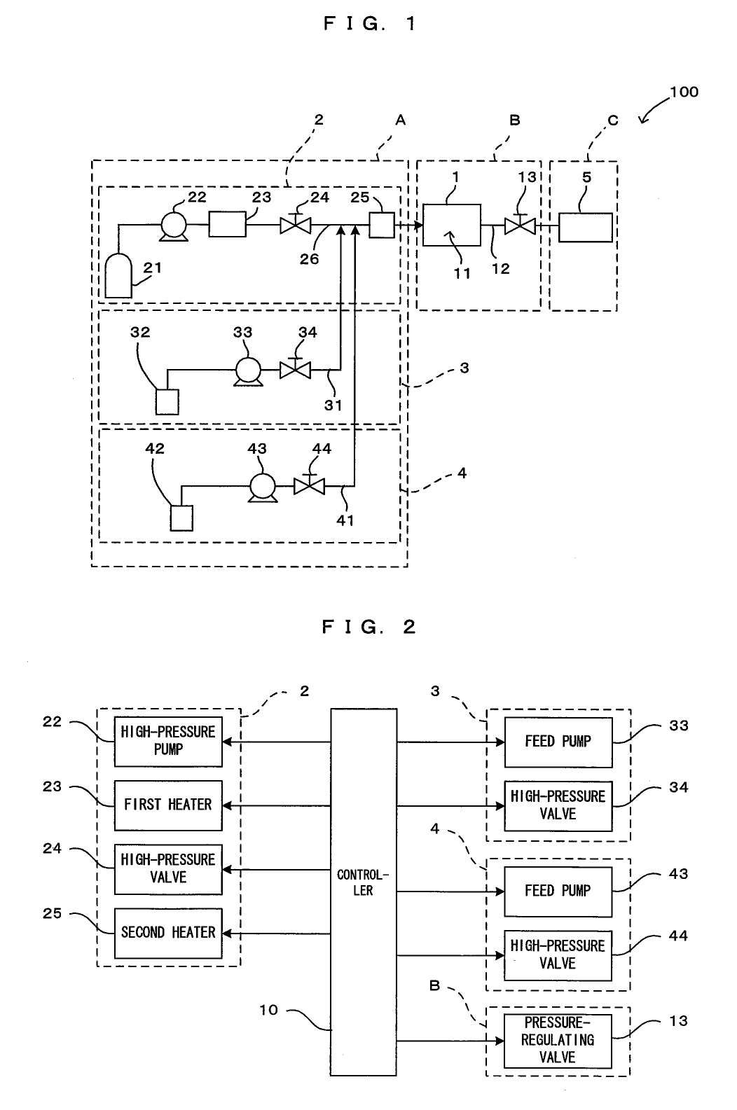

FIG. 1 is a drawing which shows a substrate processing apparatus which is able to implement a first embodiment of a substrate processing method according to the invention. FIG. 2 is a block diagram which shows an electric structure for controlling the substrate processing apparatus of FIG. 1. A substrate processing apparatus 100 is for form an oxide film on a surface of a substrate such as an approximately circular semiconductor wafer held in a processing chamber 11 which is formed inside a pressure container 1. The apparatus feeds a mixture of supercritical carbon dioxide (hereinafter called ‘SCCO2’) and solvent into the processing chamber 11 as a processing fluid to form the oxide film. Structure and operations of this substrate processing apparatus will now be described in detail.

This substrate processing apparatus 100 is equipped with three main units, which are (1) a processing fluid supply unit A which prepares the processing fluid and supplies the same to the processing chamber 11, (2) a film forming unit B which has the pressure container 1, forms the oxide film inside the processing chamber 11 of the pressure container 1 using the processing fluid, and (3) a reservoir unit C which collects and holds carbon dioxide used for film formation.

Of these units, the processing fluid supply unit A includes a high-pressure carbon dioxide supplier 2 for pressure-feeding SCCO2 toward the pressure container 1, a purified water supplier 3 for supplying purified water, and a methanol supplier 4 for supplying methanol.

The high-pressure carbon dioxide supplier 2 includes a high-pressure fluid reservoir tank 21 and a high-pressure pump 22. In the event that SCCO2 is used as high-pressure carbon dioxide, it is usually liquid carbon dioxide that is stored within the high-pressure fluid reservoir tank 21. Further, a fluid may be cooled in advance in a supercooling device (not shown) for prevention of gasification inside the high-pressure pump 22. As the high-pressure pump 22 pressurizes this fluid, high-pressure liquid carbon dioxide is obtained. The output side of the high-pressure pump 22 is connected with the pressure container 1 by a high-pressure pipe 26 in which a first heater 23, a high-pressure valve 24 and a second heater 25 are interposed. The high-pressure valve 24 opens in response to an open/close command received from a controller 10 which controls the entire apparatus, the high-pressure liquid carbon dioxide pressurized by the high-pressure pump 22 is heated up by the first heater 23, whereby SCCO2 is obtained as high-pressure carbon dioxide, and then the SCCO2 is pressure-fed directly to the pressure container 1. In addition, the high-pressure pipe 26 branches out between the high-pressure valve 24 and the second heater 25. One branch pipe 31 is connected with a purified water reservoir tank 32 of the purified water supplier 3, whereas the other branch pipe 41 is connected with a methanol reservoir tank 42 of the methanol supplier 4.

When purified water is fed from the purified water supplier 3 to the high-pressure pipe 26 via the branch pipe 31, the purified water is mixed into the SCCO2. Further, when methanol is fed to the high-pressure pipe 26 from the methanol supplier 4 via the branch pipe 41, the methanol is mixed into the SCCO2. Further, when purified water and methanol are fed to the high-pressure pipe 26 via the branch pipe 31 and 41, respectively, the purified water and the methanol are mixed into the SCCO2. According to this embodiment, each respective purified water and methanol is prepared as active chemical species for oxide film forming, i.e. a solvent containing the —OH functional group (hydroxyl), and at least either one of purified water and methanol is mixed with the SCCO2 to prepare a processing fluid for oxide film forming. Further, the processing fluid is controlled at desired processing temperature with the second heater 25. Likewise, the second heater 25 is provided with a function to precisely control the temperature of the processing fluid at the location right before the pressure container 1.

The purified water supplier 3 includes the purified water reservoir tank 32 which stores purified water which is a solvent as described above. The purified water reservoir tank 32 is connected with the high-pressure pipe 26 by the branch pipe 31. Further, a feed pump 33 and a high-pressure valve 34 are interposed in the branch pipe 31. Hence, as the high-pressure valve 34 opens and closes in response to an open/close command received from the controller 10, the purified water inside the purified water reservoir tank 32 is fed into the high-pressure pipe 26, whereby the processing fluid (SCCO2+purified water) is prepared. The processing fluid is then supplied to the processing chamber 11 of the pressure container 1.

On the other hand, the methanol supplier 4 supplies methanol which is another solvent, and includes the methanol reservoir tank 42 which stores methanol. The methanol reservoir tank 42 is connected with the high-pressure pipe 26 by the branch pipe 41. Further, a feed pump 43 and a high-pressure valve 44 are interposed in the branch pipe 41. Hence, as the high-pressure valve 44 opens and closes in response to an open/close command received from the controller 10, the methanol inside the methanol reservoir tank 42 is fed into the high-pressure pipe 26, whereby the processing fluid (SCCO2+methanol) is prepared. The processing fluid is then supplied to the processing chamber 11 of the pressure container 1. The high-pressure valves 34 and 44 are opened simultaneously according to the open/close command from the controller 10 to feed purified water and methanol to the high-pressure pipe 26, so as to prepare the processing fluid (SCCO2+purified water+methanol). Then the processing fluid is supplied to the processing chamber 11 of the pressure container 1. According to this embodiment, types of processing fluid and mixing ratio for processing fluid can be changed preferentially by controlling the high-pressure valves 34 and 44 with the controller 10. Of course, it is also possible to supply only SCCO2 to the processing chamber 11 of the pressure container 1, by closing both high-pressure valves 34 and 44. According to this embodiment, the purified water from the purified water supplier 3 and the methanol from the methanol supplier 4 are mixed in the high-pressure pipe 26. However, it is also acceptable to prepare a liquid (solvent) in advance, by mixing purified water and methanol at predetermined ratio. In this case, instead of the suppliers 3 and 4, a supplier provided with identical structure to them can be installed so that the mixed liquid (purified water+methanol) can be stored in the storage tank of the supplier. Then, the mixed liquid in the storage tank is fed to the high-pressure valve 26, by controlling open/close operation of the high-pressure valve according to an open/close command from the controller 10, to prepare the processing fluid (SCCO2+purified water+methanol).

In the film forming unit B, the pressure container 1 is communicated with a reservoir section 5 of the reservoir unit C via a high-pressure pipe 12. Further, a pressure-regulating valve 13 is interposed in this high-pressure pipe 12. Hence, the processing fluid or the like inside the pressure container 1 is discharged to the reservoir section 5 as the pressure-regulating valve 13 opens in response to an open/close command received from the controller 10. On the other hand, as the pressure-regulating valve 13 closes, the processing fluid is locked inside the pressure container 1. Further, it is possible to adjust the pressure inside the processing chamber 11, by controlling opening and closing of the pressure-regulating valve 13.

The reservoir section 5 of the reservoir unit C may be a vapor-liquid separation container or the like. The vapor-liquid separation container separates the SCCO2 into a gas component and a liquid component which will be individually discarded through separate routes. Alternatively, the respective components may be collected (and if necessary purified) and reused. The gas component and the liquid component separated from each other by the vapor-liquid separation container may be discharged out of the system via separate paths.

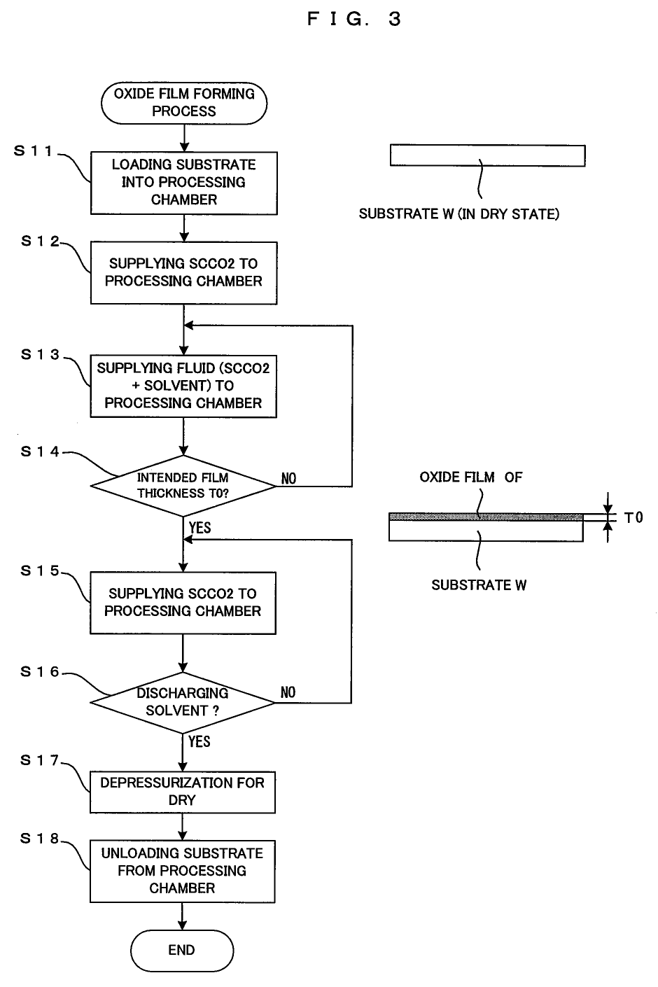

Next, the processing of oxide film formation by means of the substrate processing apparatus having the structure above will now be described referring to FIG. 3. FIG. 3 is a flow chart which shows the first embodiment of the substrate processing method according to the invention. While this apparatus is in an initial state, the valves 13, 24, 34 and 44 are all closed and the pumps 22, 33 and 43 are in a halt.

When a handling apparatus such as an industrial robot and the like, or a transportation mechanism loads one substrate W whose surface is dry at a time into the processing chamber 11, the processing chamber 11 is closed, which completes preparation for the processing (Step S11). Following this, after the high-pressure valve 24 opens, thereby making it possible to pressure-feed SCCO2 into the processing chamber 11, the high-pressure pump 22 activates and pressure-feeding of SCCO2 into the processing chamber 11 starts (Step S12). The SCCO2 is thus pressure-fed into the processing chamber 11, and the pressure inside the processing chamber 11 rises gradually. As the pressure-regulating valve 13 opens and closes under control in accordance with an open/close command from the controller 10 at this stage, the pressure inside the processing chamber 11 is kept constant, e.g., approximately at 20 MPa. This pressure adjustment by means of control of opening and closing of the pressure-regulating valve 13 continues until depressurization described later completes. In the case where adjustment of the temperature in the processing chamber 11 is necessary in addition, the processing chamber 11 may be set to a temperature suitable to surface processing using a heater (not shown) disposed in the vicinity of the pressure container 1. As described above, according to this embodiment, the processing condition with regard to the pressure and temperature of SCCO2 is controllable.

The temperature and pressure of SCCO2 can be set as follows. Specifically, “high-pressure carbon dioxide” means fluid with a pressure over 1 MPa according to this invention. The temperature over 31 degrees Celsius and 7.4 MPa is suffice to transform carbon dioxide in supercritical state. From this standpoint, it is desirable to use SCCO2 at 8 to 30 MPa. As for temperature, it is desirable to perform processing at 40 to 150 degrees Celsius and even more desirable to perform at 60 to 90 degrees Celsius.

Next, a processing fluid is prepared by feeding purified water and/or methanol as a solvent according to this invention to the high-pressure pipe 26 to be mixed with the SCCO2 (Preparation process). Then, the processing fluid is supplied to the processing chamber 11 (Step S13). More specifically, in case that only purified water is used as a solvent, the high-pressure valve 34 is opened, while the feeding pump 33 is activated. Consequently, purified water as a solvent for oxide film forming is fed from the purified water storage tank 32 to the high-pressure pipe 26 via the branch pump 31 to be mixed with the SCCO2, so that a processing fluid is prepared.

Further, in case that only methanol is used as a solvent, the high-pressure valve 44 is opened while the feeding pump 44 is activated. Consequently, methanol as a solvent for oxide film forming is fed from the methanol storage tank 42 to the high-pressure pipe 26 via the branch pump 41 to be mixed with the SCCO2 so that a processing fluid is prepared.

Further, in case that purified water and methanol are used as solvents, purified water and methanol are mixed with the SCCO2 by performing the aforementioned operation simultaneously so as to prepare a processing fluid. According to this embodiment, mixing amount and mixing ratio of the purified water and the methanol can be adjusted independently from each other by controlling the open/close operation of the high-pressure valves 34 and 44, thereby making the processing condition of solvent concentration controllable. Moreover, since the objective of this invention is to form an ultra-thin film at high quality, it is desirable to control concentration of the solvent in the SCCO2 at 0.1-20 mass %. This is because solvent concentration below 0.1 mass % will cause shortage of the active chemical species supplied from the solvent in absolute amount, thereby making it difficult to form an oxide film. On the contrary, the solvent concentration exceeding 20 mass % will cause the active chemical species to be rich in the proximity of the surface, thereby making it difficult to form an ultra-thin oxide film.

As described above, forming of an oxide film OF (oxide film forming process) on the substrate W begins when supplying of the processing fluid to the processing chamber starts. On this occasion, it is also acceptable to supply the processing fluid (SCCO2+purified water, SCCO2+methanol, or SCCO2+purified water+methanol) to the processing chamber 11 and seal it within the processing chamber to continue the forming process of oxide film. Further, it is also acceptable to form an oxide film while feeding the SCCO2 and the solvent (purified water, methanol) continuously and keeping a pressure level within the processing chamber 11 constant by controlling open/close of the pressure adjustment valve. However, provided that the active chemical species decrease as the oxide film is formed, it is desirable to keep constant flow of the processing fluid as described in the latter case.

When the oxide film OF is formed in intended film thickness T0, for example T0=1 nm (YES for Step S14), feeding of the solvent is stopped, whereas pressure feeding of the SCCO2 continues so that the only SCCO2 is supplied to the processing chamber 11 (Step S15). As a result, a solvent ingredient, which exists on the surface of the substrate and within the processing chamber 11, is discharged to the storage 5 via the high-pressure pipe 12 and the pressure adjustment valve 13. (Rinsing process). When all of the solvent ingredient on the surface of the substrate and within the processing chamber 11 are discharged (YES for Step S16), feeding of the SCCO2 is stopped. That is, while the high-pressure pump 22 is stopped to stop pressure feeding of the SCCO2, supply of carbon dioxide from the high-pressure fluid storage tank 21 is stopped by closing the valve 24, etc. Then, the interior of the processing chamber 11 is returned to normal pressure by controlling open/close of the pressure adjustment valve 13 (Step S17). The SCCO2 that remains within the processing chamber 11 becomes gas and evaporate during this pressure reduction process. This allows that the substrate W is dried without encountering problems such as leaving stains on the surface of the substrate. Furthermore, due to increase in fine patterns forming on the surface of the substrate recently, the problem in which the fine patterns are destroyed during drying process has been highlighted. However, such a problem can be resolved by using reduced-pressure drying process. Also, pre-set time control can be used for YES/NO judgment for the Steps S14 and 16.

Then, when the interior of the processing chamber 11 is returned to the normal pressure, the processing chamber 11 is opened to unload the substrate W with the oxide film formed thereon, by using the handling apparatus or transport apparatus such as industrial robot, etc (Step S18). This will complete a series of surface processes, i.e. surface film forming process+rinsing process+drying process. Then, when the next unprocessed substrate is transported, the aforementioned operation is repeated.

As described above, according to this first embodiment, while the purified water and the methanol, which are used as a solvent, are mixed with the SCCO2 for preparing the processing fluid, the processing fluid (SCCO2+purified water, SCCO2+methanol or SCCO2+purified water+methanol) is brought to contact with the surface of the substrate W so that oxide film OF is formed onto the surface of the substrate. This processing fluid uses the SCCO2 which is chemically inactive against the substrate W as a carrier medium, while the —OH functional group as active chemical species are dispersed in the SCCO2. This allows the oxide film OF to be formed while preventing the active chemical species from excessively present in the atmosphere contacting the surface of the substrate. As a result, excessive forming of an oxide film is prevented. Moreover, since highly motile and highly concentrated the SCCO2, which is chemically inactive against the substrate W, is used as a carrier medium with the active chemical species mixed therein, the active chemical species exist in excellent diffusiveness and in great quantity in spite of small amount of solvent. Therefore, fresh active chemical species are supplied constantly to the surface of the substrate to react excellently with the surface of the substrate, to form an oxide film OF. As a result, a super-thin and good quality oxide film OF is formed uniformly on the surface of the substrate W.

According to this embodiment, since the oxide film forming process is performed by using the SCCO2, the oxide film OF is formed at the temperature ranging between 40 and 150 degrees Celsius thereby enabling the oxide film OF to be formed at significantly lower temperature than conventional technology. As a result, a high quality oxide film OF can be formed without causing problems, even if impurities exist in the substrate. For example, it has been confirmed through experiments wherein a high quality oxide film OF can be obtained when the oxide film forming process is performed against a silicon substrate with a specific process condition as follows. That is, while interior of the processing chamber 12 is kept at 80 degrees Celsius in temperature with a pressure at 13.5 MPa, the processing chamber 11 is filled only with SCCO2 (Step S12). Then, the purified water and the methanol with mass ratio of 5:95 as a solvent are fed to the high-pressure pipe 26, wherein the solvents are mixed with the SCCO2 to prepare the processing fluid (SCCO2+purified water+methanol) to be supplied to the processing chamber 11 (Step S13). This supplying state is continued for approximately 40 minutes. Subsequently, only solvent supply is stopped, while only SCCO2 continues to be supplied to the processing chamber 11 for approximately 10 minutes (Step S15). With this processing condition, a high quality oxide film OF was obtained. Also, in the case that the pressure condition is set at 19.5 Mpa, a high quality oxide film OF was obtained in the same way as described above.

Although mixture of the purified water and the methanol is used as a solvent, it is also acceptable to use only purified water or only methanol. For example, it has been confirmed in experiments wherein a high quality oxide film OF can be obtained when the oxide film forming process is performed against a silicon substrate with a specific process condition as follows. That is, while interior of the processing chamber 12 is kept at 80 degrees Celsius in temperature with a pressure at 13.5 MPa, the processing chamber 11 is filled only with the SCCO2 (Step S12). Then, only methanol as a solvent is fed to the high-pressure pipe 26, wherein the solvent is mixed with the SCCO2 to prepare the processing fluid (SCCO2+methanol) to be supplied to the processing chamber 11 (Step S13). This supplying state is continued for approximately 40 minutes. Subsequently, only solvent supply is stopped, while only SCCO2 continues to be supplied to the processing chamber 11 for approximately 10 minutes (Step S15). With this processing condition, a high quality oxide film OF was obtained. Also, in the case that the pressure condition is set at 19.5 MPa, a high quality oxide film OF is obtained in the same way as described above.

Further, according to the first embodiment, process conditions such as SCCO2 temperature and pressure, time for each step and solvent density can be controlled by controlling each portion of the apparatus according to the controlling command from the controller 10. Therefore, film thickness of the oxide film OF formed onto the substrate can be adjusted with high precision by controlling the processing condition. In particular, to be described hereafter, in case that the oxide film OF is formed as a base for high-permittivity film, it is required to form a super thin film with accurate film thickness. The substrate processing method related to this embodiment can accurately meet such a requirement, and is claimed to be a useful substrate processing method.

### Second Embodiment

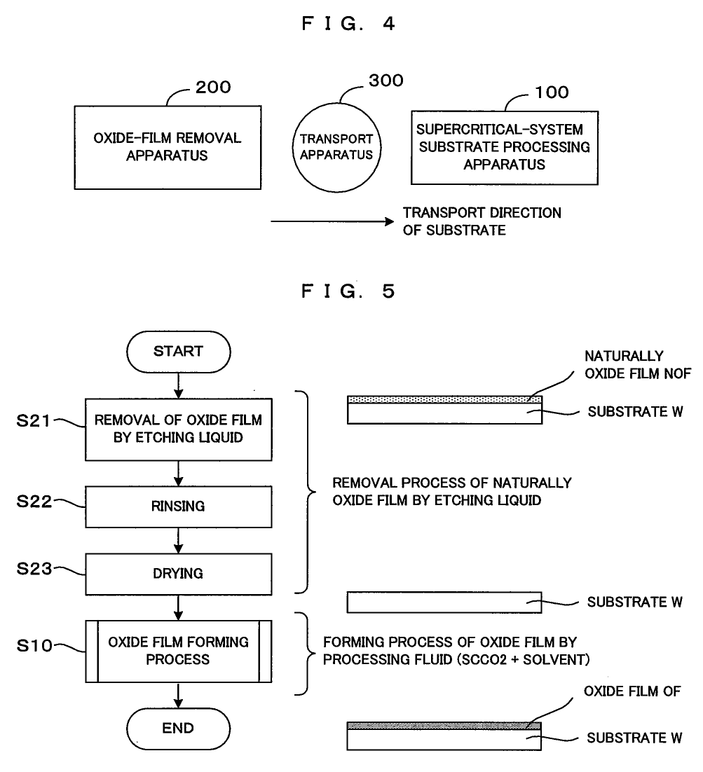

FIG. 4 is a diagram showing a substrate processing system, capable of performing a second embodiment. FIG. 5 is a flow chart showing the substrate processing method of the second embodiment related to this invention. This substrate processing system is equipped with an oxidized-film removal apparatus 200 and a transport apparatus 300, in addition to the substrate processing apparatus 100 of the FIG. 1. This oxide film removal apparatus 200 uses an etchant, for example, an etching liquid that essentially contains hydrogen fluoride, to remove a naturally oxide film NOF adhering to the surface of the substrate W. Proposals on many types of oxide film removal apparatus have been made, with a representative one being so-called rotary oxide film removal apparatus, wherein a substrate held by a spin chuck is rotated while etching liquid is supplied to the substrate W. In this apparatus 200, a substrate W is rotated while an etching liquid is supplied to the substrate W, so that a naturally oxide film NOF adhering to the substrate W is removed by etching (Step S21). Then, after the supply of the etching liquid is stopped, a rinsing liquid such as purified water and alcohol, etc is supplied to the substrate while keeping the substrate rotate so as to rinse off the etching liquid from the substrate W (Step S22). When the etching ingredient is completely discharged from the surface of the substrate W, the supply of the rinsing liquid is stopped and the substrate W is rotated at higher speed for drying (Step S23). Hence, the substrate W is obtained, with a dry surface and the naturally oxide film NOF completely removed.

Further, in this substrate processing system, the transport apparatus 300 is disposed between the oxide film removal apparatus 200 and the substrate processing apparatus 100, for the purpose of transporting the substrate W. The substrate transport apparatus 300 transports the substrate W, which is received oxide film removal process, to the substrate processing apparatus 100. The substrate processing apparatus 100 performs the oxide film forming process, similar to the first embodiment, to the substrate W, which is transported as described above, in order to form a high quality and ultra-thin oxide film OF. (Step S10)

As described above, according to this second embodiment, while the processing fluid is prepared by mixing the purified water and/or the methanol with SCCO2, similar to the first embodiment, the processing fluid (SCCO2+purified water, SCCO2+methanol, or SCCO2+purified water+methanol) is brought into contact with the surface of the substrate W. This causes the oxide film OF be formed onto the surface of the substrate W. Therefore, the same effect as the first embodiment is obtained.

When the substrate W is exposed to the air, a naturally oxide film NOF is formed onto the surface of the substrate W. It is difficult to form excellently an oxide film on the surface of the substrate if the naturally oxide film NOF is formed thereon. As a solution, the second embodiment adopts the substrate processing method (oxide film forming process) related to this invention, wherein the surface of the substrate is dried, while the naturally oxide film NOF is removed from the surface of the substrate, prior to the forming of the oxide film OF on the surface of the substrate. Further, since the substrate W is immediately transported to the substrate processing apparatus 100 which the oxide film is formed, the high quality oxide film OF can be formed onto the substrate W without being affected by the naturally oxide film NOF.

### Third Embodiment

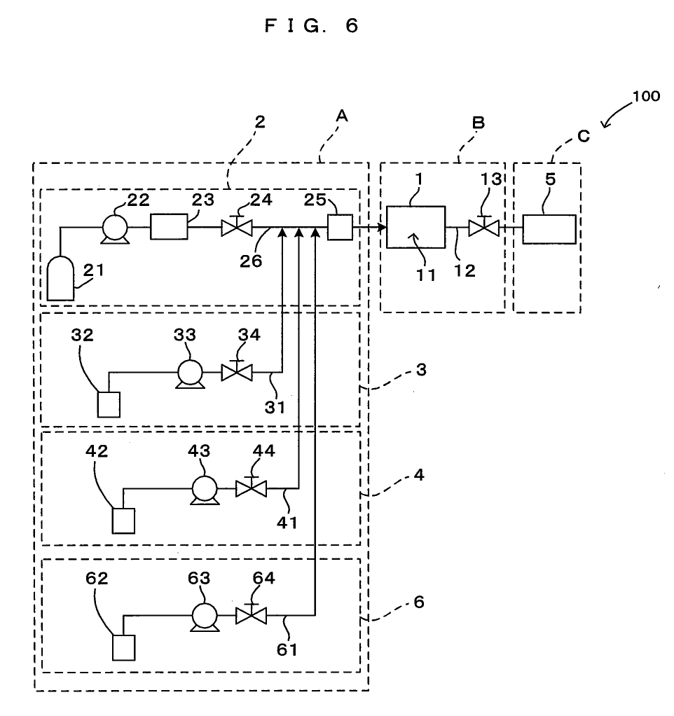

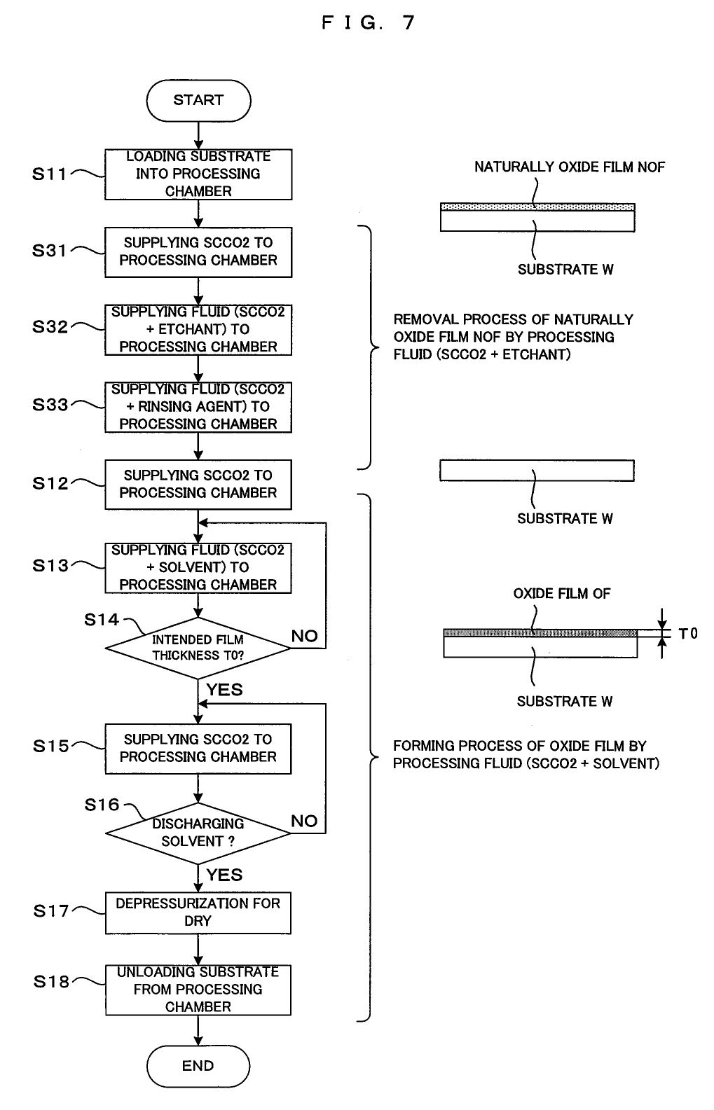

Methods for removing naturally oxide film NOF from a substrate W have been proposed so far. The methods include a supercritical method wherein an etching process is performed by using a mixture of etchant and SCCO2, in addition to a so-called wet system wherein an etching liquid is supplied to a substrate W. Therefore, an arrangement may be made to remove the naturally oxide film NOF via supercritical method, instead of the wet-system-based oxide film removal method. In case that a supercritical system is used, a naturally oxide film NOF removal process and the oxide film OF forming process can be performed sequentially within the same chamber. Hereafter, a detailed description will be made on a third embodiment of this invention with reference to FIGS. 6 and 7.

FIG. 6 is a diagram showing a substrate processing system, capable of performing the third embodiment. FIG. 7 is a flowchart showing the third embodiment of the substrate processing method related to this invention. This substrate processing apparatus 100 is further equipped with a hydrogen fluoride supplier 6 to supply hydrogen fluoride as an etchant to the processing fluid supplying unit A. This hydrogen fluoride supplier 6 is installed for the purpose of supplying hydrogen fluoride as an etchant and is equipped with a hydrogen fluoride storage tank 62, as shown by FIG. 6. This storage tank 62 is connected with a high-pressure pipe 26, via a branch pipe 61. Further, this branch pipe 61 is coupled with a feeding pump 63 and a high-pressure valve 64. Therefore, controlling open/close operation of the high-pressure valve 64 according to an open/close command from the controller 10 allows a feeding of hydrogen fluoride in the hydrogen fluoride storage tank 62 to the high-pressure valve 26, thereby preparing a processing fluid (SCCO2+HF). Consequently, the processing fluid is supplied to the processing chamber 11 of the pressure container 1. In addition, methanol may be supplied simultaneously from the methanol supplier 4, as a compatibilizer, to be used in conjunction with the processing fluid, which is prepared by mixing the hydrogen fluoride and the ethanol with the SCCO2.

According to this embodiment, the purified water from the purified water supplier 3, the methanol from the methanol supplier 4 and the hydrogen fluoride from the hydrogen fluoride supplier 6 are mixed, as appropriate, in the high-pressure valve 26. Alternatively, two types of mixture liquid may be prepared in advance at a predetermined ratio. These two types are: a first liquid (etchant) which is prepared by mixing the hydrogen fluoride, the purified water and the methanol at a first predetermined ratio; and a second liquid (solvent) which is prepared by mixing the purified water and the methanol at a second predetermined ratio. In this case, instead of the suppliers 3, 4 and 6, two suppliers having a structure identical to the suppliers 3, 4 and 6 can be installed. While the first liquid (hydrogen fluoride+purified water+methanol) is stored in the storage tank of one of the suppliers, the second liquid (purified water+methanol) can be stored in the storage tank of the other. Then, controlling open/close operation of the high-pressure valve installed in one of the suppliers according to an open/close command from the controller 10 allows the feeding of the first liquid in the storage tank to the high-pressure pipe 26, thereby preparing the processing fluid (SCCO2+hydrogen fluoride+purified water+methanol) (Step S32). Using with the processing fluid, the naturally oxide film removal process is performed. Further, controlling open/close operation of the high-pressure valve installed in the supplier of the other according to open/close command from the controller 10 allows the feeding of the second liquid in the storage tank to the high-pressure pipe 26 thereby preparing a processing liquid (Step S13). Using with the processing fluid, an oxide film forming process is performed.

Next, a description will be made on the substrate processing method in the third embodiment with reference to FIG. 7. Specifically, according to this embodiment, the removal process of naturally oxide film NOF and the forming process of oxide film OF are conducted sequentially within the same processing chamber 11.

According to this embodiment, when one the substrate W with a dry surface is loaded to the processing chamber 11 by the handling apparatus or the transport apparatus such as an industrial robot, etc. (Step S11), the naturally oxide film NOF removal process is performed (Step S31-S33), prior to the oxide film forming process (Step S31-S33). During this oxide film removal process, after the high-pressure valve 24 is opened to allow the SCCO2 to be pressure fed from the high-pressure carbon dioxide supplier 2 to the processing chamber 11, the high-pressure pump 22 is activated to start the pressure feeding of the SCCO2 to the processing chamber 11. Consequently, the SCCO2 is pressure fed to the processing chamber 11, gradually increasing the pressure in the processing chamber.

Then, according to the control command from the controller 10, the hydrogen fluoride as an etchant is fed to the high-pressure pipe 26 to be mixed with the SCCO2 so as to prepare the processing fluid. Then, the processing fluid is supplied to the processing chamber 11 (Step S32). In case that methanol is used as a phase solvent, the methanol is fed to the high-pressure valve 26 via the branch pipe 41 from the methanol storage tank 42 by opening the high-pressure valve 44, while the feeding pump 43 is activated simultaneously with feeding of hydrogen fluoride. As described above, the processing fluid (SCCO2+hydrogen fluoride, or SCCO2+hydrogen fluoride+methanol) containing etchant, is supplied to the processing chamber 11, whereby the naturally oxide film NOF adhering to the surface of the substrate W in the processing chamber is etching-removed.

When this etching removal is completed, the feeding of hydrogen fluoride from the hydrogen fluoride supplier 6 to the high-pressure pipe 26 is stopped. Consequently, the processing fluid (SCCO2+methanol) wherein only methanol is mixed with SCCO2, is supplied to the processing chamber 11, so that a rinsing process is performed to the substrate W. Then, after the rinsing process is completed, the supply of methanol from methanol supplier 4 is stopped so that only SCCO2 is supplied to the processing chamber 11 as a processing fluid (Step S12). This causes the methanol ingredient to be discharged from the processing chamber 11, to fill up the processing chamber 11 with the SCCO2. This completes the removal process of naturally oxide film NOF by the processing fluid that includes the etchant as well as starting the forming process of the oxide film OF. Since the forming process of oxide film OF is identical to the first embodiment, the description thereof is dispensed with.

As described above, in this third embodiment, similar to the first embodiment, the processing fluid is prepared by mixing the purified water and the methanol with the SCCO2, whereas the processing fluid (SCCO2+purified water, SCCO2+methanol, or SCCO2+purified water+methanol) is brought into contact with the surface of the substrate W, so as to form the oxide film OF on the surface of the surface W. Thus, the effect identical to the first embodiment is obtained. Further, since the naturally oxide film NOF is removed from the surface of the substrate by the substrate processing method (oxide film forming) of this invention, in the same manner as the second embodiment, prior to the oxide film OF being formed onto the surface of the substrate, high quality oxide film OF can be formed onto the substrate W.

In addition, according to the third embodiment, since the naturally oxide film removal process and the oxide film forming process are performed sequentially within the same processing chamber 11, following effect is obtained. That is, during the naturally oxide film removing process (Step S3) wherein the solvent to be mixed with the SCCO2 is switched, the hydrogen fluoride as an etchant is mixed with the SCCO2, whereas a chemical compound having the —OH functional group is mixed therewith during the oxide film forming process (Step S13). This means that the processing content can be changed only by switching a solvent ingredient to be mixed with the SCCO2, therefore the interval can be shortened between the oxide film removal process and the oxide film forming process. As a result, throughput can be improved significantly compared with the second embodiment. Further, the use of SCCO2, which is always chemically inactive against the substrate W, as a carrier medium ensures the processing to be carried out excellently with great stability.

### Fourth Embodiment

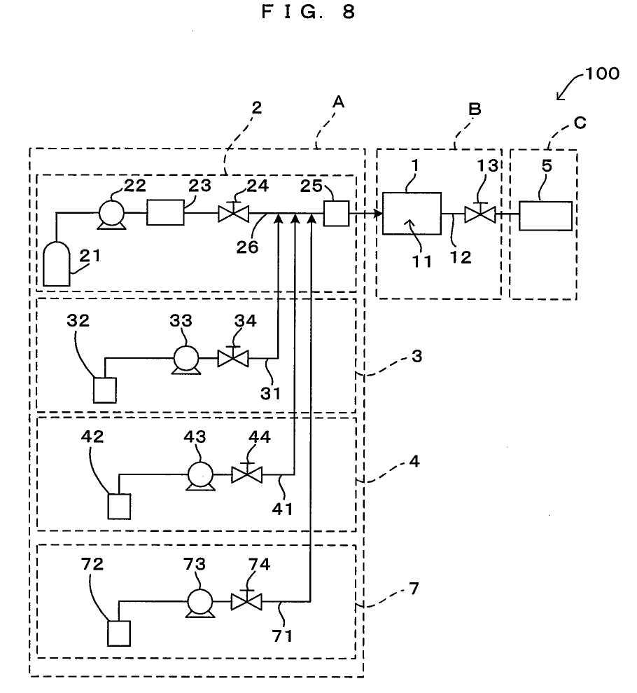

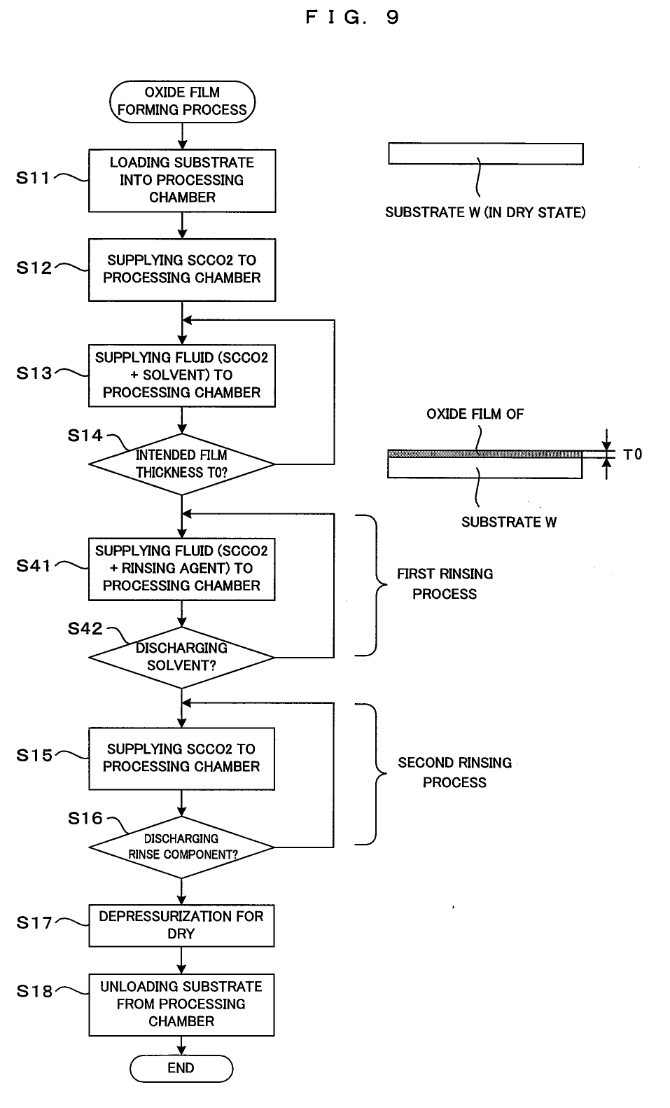

According to the forgoing embodiment, after the oxide film OF is formed by using the purified water and the methanol as a chemical compound having the —OH functional group, the solvent ingredient is rinsed off by using the SCCO2 only. The chemical compound herein is not limited to the purified water and the methanol, but other chemical compound having the —OH functional group can be used. However, in case of selecting some chemical compound as a solvent, it may be difficult to rinse off the solvent sufficiently with the rinsing process using SCCO2 only. In the case such solvents are used, it is desirable to divide the rinsing process after the oxide film forming process into two phases. Hereafter is a description on the fourth embodiment of this invention with reference to FIGS. 8 and 9.

FIG. 8 is a diagram showing a substrate processing system, capable of performing a fourth embodiment. This substrate processing apparatus 100 is equipped with the purified water supplier 3 and an IPA supplier 7 for the purpose of supplying a chemical compound having the —OH functional group as a solvent to the processing fluid supplying unit A. This IPA supplier 7 is provided with an IPA storage tank 72 to store isopropyl alcohol (IPA), with which an oxide film OF is formed. This IPA storage tank 72 is connected with a branch pipe 71 which is branched off from the high-pressure pipe 26 between the high-pressure valve 24 and the second heater 25. This branch pipe 71 is coupled with a feeding pump 73 and a pressure valve 74. Therefore, controlling open/close operation of the high-pressure valve 74 according to an open/close command from the controller 10 allows the isopropyl alcohol in the IPA storage tank 72 to be fed to the high-pressure pipe 26. Further, according to this embodiment, simultaneously with the feeding of the isopropyl alcohol to the high-pressure valve 26, the purified water is fed from the purified water supplier 3. As a result, the isopropyl alcohol and the purified water are mixed with the SCCO2, thereby the processing fluid (SCCO2+purified water+IPA) is prepared and supplied to the processing chamber 11 of the pressure container 1. As described above, in the context of this embodiment, the isopropyl alcohol and the purified water are used as a solvent.

According to this embodiment, the methanol supplier 4 is installed, wherein the methanol functions as a rinsing agent to rinse off the isopropyl alcohol from the substrate surface completely. This means that the methanol is used only during the first rinsing process, as described hereafter.

FIG. 9 is a flowchart showing the fourth embodiment of the substrate processing method. Significant differences between this fourth embodiment and the first embodiment lie with the point where mixture of the isopropyl alcohol and the purified water is used as a solvent and with the point that rinsing process consists of two steps. Since all the other points are identical, a description hereafter will focuses on the differences.

First, when one substrate W with dry surface is loaded to the processing chamber 11 (Step S11), the pressure feeding of SCCO2 to the processing chamber starts (Step S12). The SCCO2 is pressure fed to the processing chamber 11 so that the pressure in the processing chamber increases gradually. Next, the purified water and the isopropyl alcohol are fed to the high-pressure pipe 26, according to the control command from the controller 10 to be mixed with the SCCO2 so that the processing fluid is prepared. Then, the processing fluid is supplied to the processing chamber 11 (Step S13). More specifically, the high-pressure valve 34 is opened while the feeding pump 33 is activated so as to feed the purified water from the purified water storage tank 32 to the high-pressure pipe 26 via the branch pipe 31. Simultaneously with this, the high-pressure valve 74 is opened while the feeding pump 73 is activated to feed the isopropyl alcohol from the IPA storage tank 72 to the high-pressure pipe 26 via the branch pipe 71. As a result, the purified water and the isopropyl alcohol are mixed with the SCCO2, thereby preparing (preparation process) the processing fluid (SCCO2+purified water+isopropyl alcohol).

Oxidized film OF starts being formed onto the substrate W when the supply of the processing fluid to the processing chamber 11 begins. Whereas the supply of the purified water and the isopropyl alcohol stops and the feeding of methanol starts when the film thickness of the oxide film OF reaches an intended film thickness T0, for example T0=1 nm (Yes for Step S14). Here, the methanol functions as a rinsing agent for the solvents. Opening the high-pressure valve 44 as well as activating the feeding pump 43 triggers the methanol to be fed to the high-pressure pipe 26 from the methanol storage tank 42 via the branch pipe 41. Then, mixing the methanol with the SCCO2 prepares the processing fluid (SCCO2+methanol) for the first rinsing (Step S41). It is also possible to use pre-set time control for YES/NO judgment in this embodiment as well.

Starting of the supply of the processing fluid to the processing chamber 11 starts the discharging of the solvent ingredient from the substrate surface and the processing chamber 11 (first rinsing process). Then, when it is confirmed that the solvent ingredient is discharged completely at Step S42, only SCCO2 is supplied to the processing chamber 11 as the processing fluid so that the second rinsing process is performed, while the supply of the methanol from the methanol supplier is stopped so that the first rinsing process is completed (Step S15), As a consequence, the methanol ingredient that exists on the substrate surface and the processing chamber 11 is discharged to the storage 5 via the high-pressure pipe 12 and the pressure adjustment valve 13 (second rinsing process). When all of the rinsing ingredient (methanol) that was used during the first rinsing process is discharged form the substrate surface and the processing chamber 11 (YES for Step S16), the high-pressure pump is stopped to stop the pressure feeding of the SCCO2. Then, the pressure in the processing chamber 11 is returned to normal, by controlling open/close of the pressure adjustment valve 13 (Step S17). Since the SCCO2 remaining in the processing chamber 11 evaporates as gas during this pressure reduction process, the substrate W can be dried without encountering problems such as stains on the surface of the substrate.

When the pressure in the processing chamber returns to normal, the processing chamber 11 is opened and the substrate W with the oxide film formed thereon is unloaded by the handling apparatus or the transport apparatus such as an industrial robot, etc. (Step S18). This completes a series of surface processes, i.e., oxide film forming process+first rinsing process+second rinsing process+drying process. When a next unprocessed substrate W is transported, foregoing operation is repeated.

As described above, in this fourth embodiment, while a processing fluid is prepared by mixing the purified water and the isopropyl alcohol as a solvent of this invention with the SCCO2, the processing fluid (SCCO2+purified water+isopropyl alcohol) is brought into contact with the surface of the substrate W, thereby forming the oxide film OF on the surface of the substrate W. Therefore, the effect identical to the first embodiment is obtained. Further, since the rinsing process is performed in two steps due to the use of the aforementioned solvent, the solvent ingredient can be discharged completely from the surface of the substrate and processing chamber 11, thereby enabling the substrate processing to be performed excellently.

### Fifth Embodiment

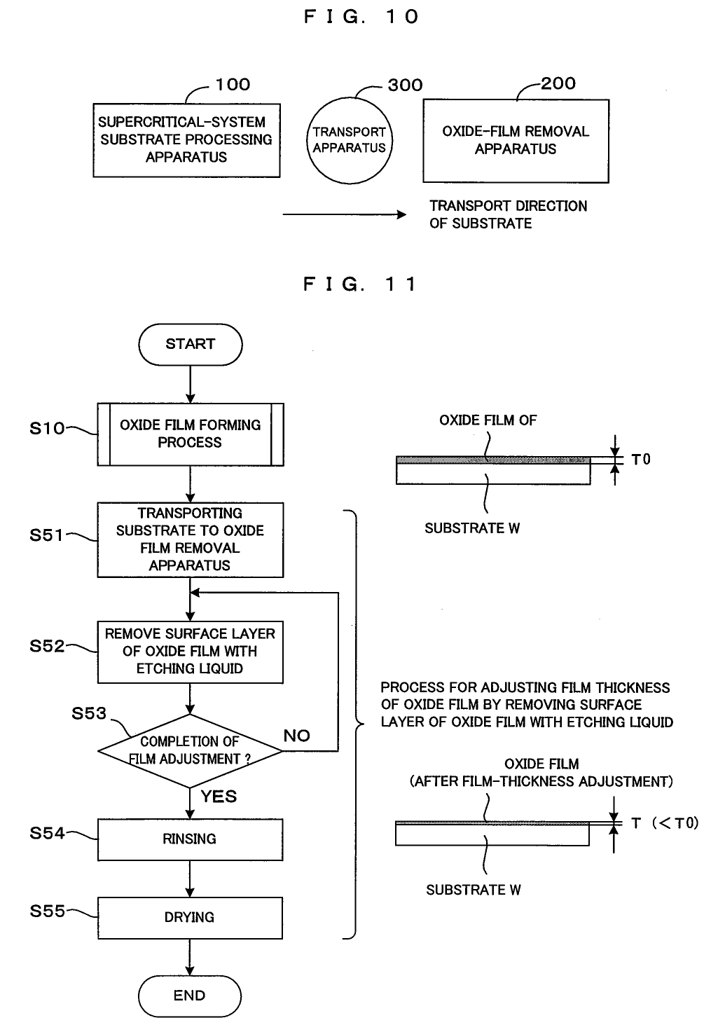

Film thickness of the oxide film OF is adjusted using the oxide film forming process according to the first and fourth embodiments. Alternatively, it is also acceptable to adjust the film thickness of the oxide film OF by removing a surface layer of the oxide film. For example, the film thickness may be controlled by means of etching after the oxide film forming process. Hereafter is a detailed description on a fifth embodiment of this invention with reference to FIGS. 10 and 11.

FIG. 10 is a diagram showing a substrate processing system, capable of performing a fifth embodiment. FIG. 11 is a flowchart showing the fifth embodiment of the substrate processing method related to this invention. This substrate processing system is equipped with the oxidized-film removal apparatus 200 and the transport apparatus 300, in addition to the substrate processing system 100, which is shown in FIGS. 1, 6 and 8. As for this oxide film removal apparatus 200, the apparatus identical to the one adopted in the second embodiment can be adopted. Specifically, this oxide film removal apparatus 200 removes the surface layer of the oxide film OF formed onto the surface of the substrate, by using an etchant for the etching of the oxide film OF, for example, by using an etching a liquid essentially containing hydrogen fluoride.

In this substrate processing system, the substrate processing identical to those of the first and fourth embodiments is performed, i.e. the oxide film forming process is performed by the substrate processing apparatus 100 (Step S10). Since the description on the content of the oxide film forming process has already been made, a description herein is dispensed with.

The substrate with oxide film formed thereon is transported to the oxide film removal apparatus 200 by the transport apparatus 300 (Step S51). In this oxide film removal apparatus 200, an etching liquid is supplied to the substrate, while the substrate W is rotated by the spin chuck in order to remove the surface layer of the oxide film OF gradually (Step S52). The amount of etching can be controlled based on the etchant density in the etching liquid, processing temperature, processing time or the like. This means that an accurate judgment on whether a film thickness adjustment process is completed or not can be made by managing the processing time based on the etchant density and processing temperature. Thus, according to this fifth embodiment, the supply of the etching liquid is stopped when the film thickness of the oxide film OF at Step S53 reaches a preset value (<T0) and thus the completion of the film adjustment is confirmed. Also, at the same time with this, the rinsing liquid such as purified water and alcohol is supplied to the substrate W while keeping the substrate W rotate to rinse off the etching liquid from the substrate W (Step S54). Further, when the etching ingredient is completely discharged from the substrate surface, the supply of the rinsing liquid is stopped and the substrate W is rotated at higher speed for drying (Step S55).

As described foregoing, in the fifth embodiment, the film thickness adjustment process (Steps S51 through S55) is performed to the substrate W with the oxide film OF formed thereon by the oxide film forming process (Step S10). Specifically, the surface layer of the oxide film OF is removed by etching so as to adjust the film thickness of the oxide film OF. Therefore, the film thickness of the oxide film OF can be adjusted with greater precision.

The arrangement of the oxide film removal apparatus 200 is not limited to the aforementioned rotary oxide film removal apparatus, but a conventionally well-known oxide film removal apparatus may be used. Particularly, the film thickness adjustment process may be performed by using the processing fluid, which is prepared by mixing the etchant with the SCCO2 and in this case, the apparatus identical to FIG. 6 can be used. Specifically, subsequent to the oxide film forming process, the processing fluid, which is prepared by mixing the etchant with the SCCO2 is brought into contact with the surface of the substrate to remove the surface layer of the oxide film OF by etching. In this substrate processing apparatus, the solvent to be mixed with the SCCO2 can be switched i.e., a chemical compound having the —OH function group can be mixed therewith during the oxide film forming process (Step S10), whereas the etchant, for example, hydrogen fluoride, can be mixed with the SCCO2 during the naturally oxide film removing process. Thus, the processing content can be changed, only by switching a solvent ingredient, which is to be mixed with the SCCO2, thereby enabling the interval between the oxide film removal process and the oxide film forming process to be shortened. As a result, throughput can be improved significantly compared with the fourth embodiment. Further, since the SCCO2, which is always chemically inactive against the substrate W, is used as a carrier medium, the processing can be performed well with great stability.

### Sixth Embodiment

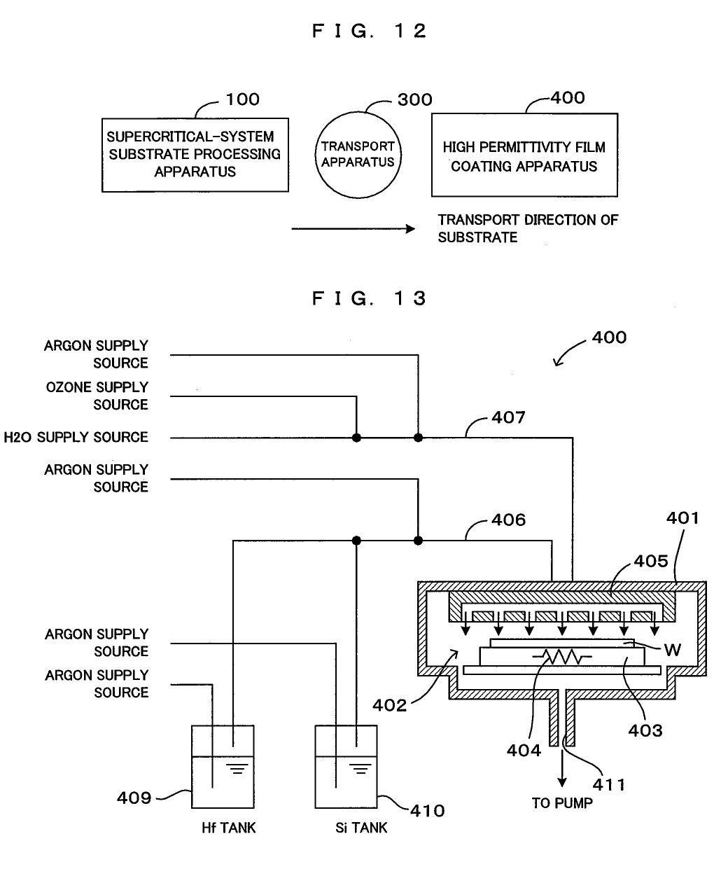

FIG. 12 is a diagram showing a substrate processing system, capable of performing a sixth embodiment. FIG. 13 is a chart showing the film forming apparatus installed in the substrate processing system of FIG. 12. This sixth embodiment is equipped with the transport apparatus 300 and a coating apparatus 400, in addition to the substrate processing apparatus 100. This coating apparatus 400 deposits high permittivity film by ALD (Atomic Layer Deposition) method on the oxide film OF formed by the substrate processing apparatus 100.

The coating apparatus 400 is provided with a vacuum vessel 401 as shown by FIG. 13. In this vacuum vessel 401, while a processing chamber 402 is installed for the purpose of performing deposition process to the substrate W, the substrate W can be held on a table 403, which is disposed inside the processing chamber 402. This table 403 is embedded with a heater 404 for heating the substrate W to film coating temperature according to an operation command from the controller, which is not shown.

Further, a rectifier 405 is disposed above the substrate W held by the table 403, for the purpose of uniformly supplying raw material gas, which is to be described later, to the entire surface of the substrate W. This rectifier 405 is provided with a plurality of outlets with each respective outlet connected with two pipes 406 and 407. Among these pipes, the first lineage of pipe 406 is connected with a gas supplier 408, which supplies the raw material gas. That is, the first lineage pipe 406 is connected with a Hf tank 409, a Si tank 410 and an argon supply source. Further, since the argon supply source is connected with each of the Hf tank 409 and Si tank 410, the argon gas supplied from each argon supply source to the tank gasifies the raw material liquid in the tank to be supplied to the surface of the substrate via the first lineage pipe 406 and the rectifier 405. The second lineage 407 is connected with an H2O supply source, an ozone supply source and the argon supply source.

Further, an exhaust outlet 411 is disposed below the vacuum vessel 401 to allow gas to be exhausted to the pump (not shown) in the processing chamber 402 via the exhaust outlet 411.

In this substrate processing system, the oxide film OF is formed onto the surface of the substrate by the substrate processing apparatus 100, at first. Then, after the substrate is transported onto the table 403 of the coating apparatus 400 by the transport apparatus 300, a hafnium oxide film (HfO2), which is one of the high permittivity films (High—k film), is formed onto the oxide film OF by ALD method.

As described above, in this sixth embodiment, the substrate forming apparatus 100 and the coating apparatus 400 are disposed next to each other with the transport apparatus 300 in-between, and the high permittivity film is formed onto the oxide film OF by the coating apparatus 400 immediately after the oxide film OF is formed by the substrate processing apparatus 100. Thus, the ultra-thin and high permittivity film can be formed onto the oxide film OF, thereby enabling the production of a high quality semi-conductor device or the like.

In the sixth embodiment, the deposition process is performed to the substrate W wherein the film thickness of the oxide film OF is adjusted to an intended thickness T0 by the oxide film forming process (Step S10). Alternatively, the arrangement can be made for the deposition process to be performed to the substrate W which went through the film thickness adjustment process.

### Seventh Embodiment

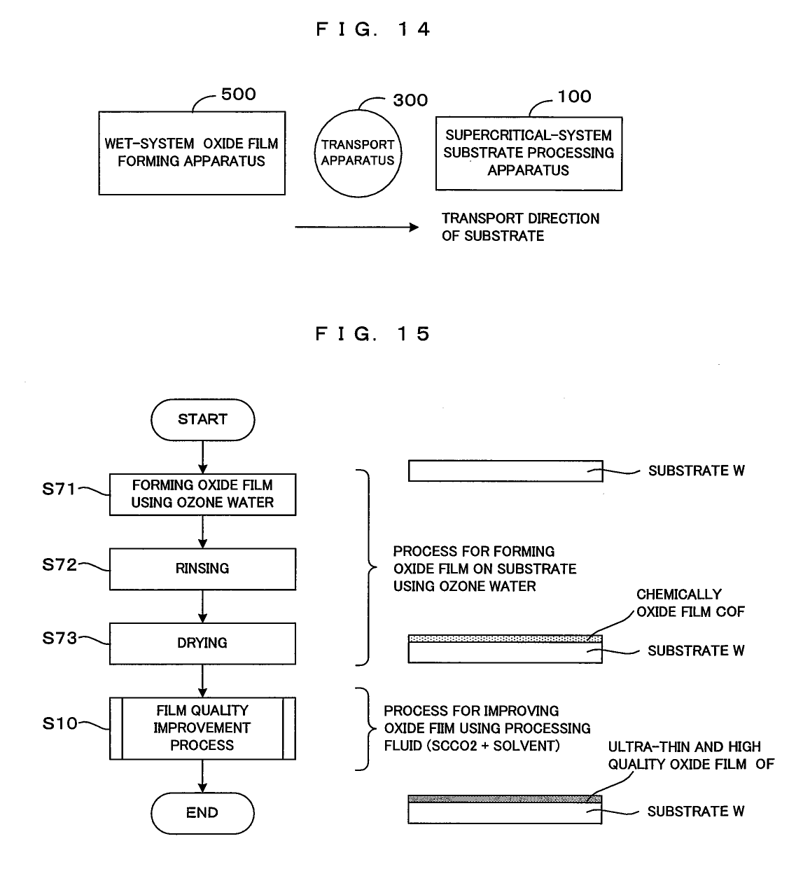

According to the above first and sixth embodiments, the high quality oxide film is newly formed onto the substrate during the state where no oxide film exists on the surface thereof. Alternatively, a high quality oxide film can be formed as follows. Specifically, a thermally oxide film, a vapor oxide film, a chemically oxide film or a vapor deposition film is formed onto the surface of the substrate in advance, then, the substrate processing apparatus 100, shown in FIGS. 1, 6 and 8, is used to improve the quality of the oxide film as well as to obtain additional growth, so as to form a high quality oxide film. Hereafter, a detailed description of the seventh embodiment will be made with reference to FIGS. 14 through 16.

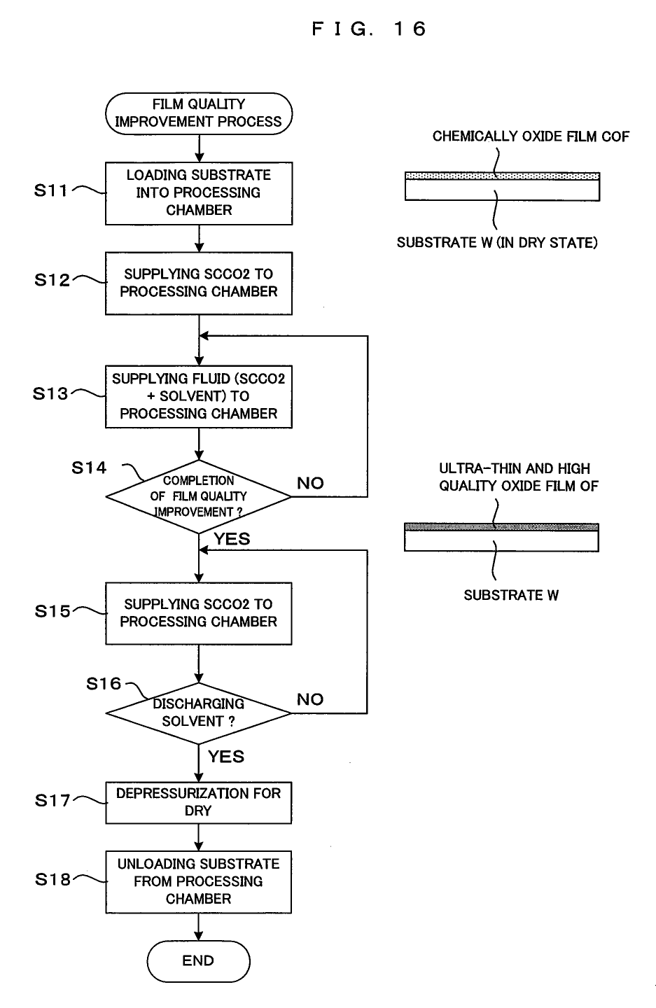

FIG. 14 is a diagram showing a substrate processing system, capable of performing a seventh embodiment. FIG. 15 and FIG. 16 are flow charts showing the seventh embodiment of the substrate processing method related to this invention. This seventh embodiment is equipped with the transport apparatus 300 and a wet-system oxide film forming apparatus 500 in addition to the substrate forming apparatus 100. This oxide film forming apparatus 500 forms a chemically oxide film COF on the surface of the substrate W by supplying ozone water thereto, as conventionally well known. Since the structure of the oxide film forming apparatus 500 is already well known, a description thereof is dispensed with.

In this oxide film forming apparatus 500, the oxide film COF is formed by supplying ozone water to the substrate W, as shown by FIG. 15 (Step S71). When the oxide film COF is formed in desired film thickness, the supply of the ozone water is stopped to rinse off ozone water form the substrate W and then a rinsing process is performed. In the rinsing process, the rinsing liquid such as purified water is supplied to the substrate W (Step S72). Subsequently, the drying process is performed to the substrate W to dry the surface of the substrate (Step S73).

The oxide film COF, which is formed by using the ozone water, is so called chemically oxide film, which entails quality issues in practical application. Since the chemically oxide film COF is formed in island shape, it is difficult for the film to be formed uniformly on the surface of the substrate and may contain substantial amount of ingredient called sub-oxide. This sub-oxide does not have stoichiometric structure such as SiO2, but has such a structure as SiOx (x=0.5 to 1.5). Therefore, the chemically structured COF cannot be used, for example, as a basis for a high permittivity film as is, and improvement of the film quality is required. Such a background of art is not limited to the chemically oxide film but similarly applicable to a thermally oxide film, a vapor oxide film, a vapor deposition film and the like.

Therefore, according to this seventh embodiment, the substrate processing method similar to those of the first embodiment and fourth embodiments is performed to the substrate W, which has a dry surface and is provided with a chemically oxide film COF on the surface thereon, so that film quality of the oxide film is improved while an additional growth of the oxide film is obtained, thereby a high quality oxide film is formed. Further, according to the seventh embodiment, while the processing steps constituting the substrate processing method are identical to that of the first embodiment, its object is to improve film quality and achieve additional growth. Therefore, a description is made separately under a title of “film quality improvement process” in this specification so as to differentiate from “oxide film forming process” in the first embodiment.

In the substrate processing method (film quality improvement process) related to the seventh embodiment, i.e. at the step S10, the substrate W is loaded from the oxide film forming apparatus 500 to the processing chamber 11 via the transport apparatus 300 as shown by FIG. 16 (Step S11). This substrate W as described above has the dry surface and is provided further with an oxide film COF on the surface. Furthermore, subsequent to the loading of the substrate W, the processing step identical to that of the first embodiment is performed.

After the high-pressure valve 24 is opened at the step S12, to allow the SCCO2 to be pressure-fed from the high-pressure carbon dioxide supplier 2 to the processing chamber 11, the high-pressure pump 22 is activated to start pressure feeding the SCCO2 to the processing chamber 11. This causes the SCCO2 to be pressure fed to the processing chamber 11 so that the processing chamber 11 is filled with the SCCO2. Next, the purified water/or methanol as a solvent is fed to the high-pressure pipe 26 according to the control command from the controller 10 so as to mix the solvent with the SCCO2 to prepare the processing fluid. Then, the processing fluid is supplied to the processing chamber 11 (Step S13). This initiates the improvement of film quality and additional growth of the chemically oxide film COF. At this time, it is also possible to continue the film quality improvement process by supplying the processing fluid (SCCO2+purified water, SCCO2+methanol, or SCCO2+purified water+methanol) to the processing chamber 11 and by sealing it within the processing chamber. Also, the film quality improvement process can be performed while keeping the pressure constant within the processing chamber by controlling open/close of the pressure adjustment valve 13 and by continuously feeding the SCCO2 and the solvent (purified water, methanol). However, considering that active chemical species decrease as oxide film forming progresses, it is desirable to keep the flow of the processing fluid as the latter case.

Although the feeding of the solvent is terminated upon the completion of the film quality improvement (Yes for the step S14), the pressure feeding of the SCCO2 continues so that the only SCCO2 is supplied to the processing chamber 11 (Step S15). Consequently, the solvent ingredient existing on the surface of the substrate and within the processing chamber 11 is discharged to the storage 5 via the high-pressure pipe 12 and the pressure adjustment valve 13 (rinsing process). Then, when the solvent ingredient is completely discharged from the surface of the substrate and the processing chamber 11 (Yes for Step S16), the high-pressure pump 22 is stopped to terminate the pressure feeding of the SCCO2. Then, pressure within the processing chamber 11 is returned to normal by controlling open/close of the adjustment valve 13 (Step S17). The substrate W is dried well during this pressure reduction process.

Then, when the pressure of the processing chamber 11 is returned to normal, the processing chamber 11 is opened to unload the substrate W with the oxide film formed thereon by the handling apparatus and the transport apparatus such as an industrial robot, etc. (Step S18). This completes a series of surface processes, i.e. film quality improvement process+rinsing process+drying process. Then, when the next substrate W is transported from the oxide film forming apparatus 500 by the transport apparatus 300, foregoing operation is repeated.

As described above, according to the seventh embodiment, while the processing fluid is prepared by the mixing purified water and/or the methanol as a solvent with the SCCO2, the processing fluid (SCCO2+purified water, SCCO2+methanol, or SCCO2+purified water+methanol) is brought into contact with the surface of the substrate W so as to improve the quality of the chemically oxide film COF, which exist on the surface of the substrate. Since highly motile and highly concentrated the SCCO2 is used as a carrier medium with active chemical species mixed into the carrier medium, the active chemical species demonstrates great diffusivity, and moreover, even a small amount of solvent contains great quantity of active chemical species. Therefore, fresh active chemical species are supplied constantly to the chemically oxide film COF to react well with the chemically oxide film COF so that film quality improvement progresses. Further, although additional growth of the oxide film occurs simultaneously with improvement of the film quality, excessive forming of the oxide film can be prevented for the following reasons. Since this processing fluid uses the SCCO2, which is chemically inactive against the substrate W as a carrier medium, while the —OH functional group (hydroxyl) disperse as active chemical species in the SCCO2, excessive presence of the actively chemical species is prevented on the surface of the substrate and near the chemically oxide film COF. As a result, an ultra-thin and high quality oxide film OF can be formed onto the surface of the substrate W.

Further, since the film quality improvement process is performed by using the SCCO2 in this embodiment, a high quality oxide film OF can be formed at the temperature ranging between 40 and 150 degrees Celsius, thereby enabling the forming of the oxide film OF at a significantly lower temperature than the conventional arts. As a consequence, even if impurities are included in the substrate, a high quality oxide film OF can be formed without causing various problems.

Further, in the seventh embodiment as well, the process conditions such as temperature and pressure of the SCCO2 and density of solvent are controllable by controlling each respective portion of the apparatus according to the control command from the controller 10. Therefore, the thickness of oxide film formed onto the substrate W can be adjusted with high precision by controlling the process conditions.

Further in the seventh embodiment, although the film quality improvement process is performed to the substrate W on which the chemically oxide film COF is formed, so as to form the high quality oxide film OF, similar film quality improvement process can be applied (Step S10) to the substrate with a thermally oxide film, a vapor oxide film and a vapor deposition film, as well.

It is also possible to adjust the film thickness of the oxide film by performing the film thickness adjustment process (Steps S51 through 55) to the substrate W, similar to the fifth embodiment after the film quality improvement process (Step S10) is performed. This enables the thickness of the oxide film OF to be adjusted even more precisely. It is also possible to perform the film forming process to the substrate W, similar to the sixth embodiment, after the film quality improvement process (Step S10) and the film thickness adjustment process are performed.

This invention is not limited to the embodiments above, but may be modified to the extent not deviating from the intention of the invention. According to the foregoing embodiment, this invention is applied to a so-called single wafer processing system wherein the substrate is processed on a per-substrate basis. However, this invention can be applied to a so-called batch process system wherein a plurality of substrates are processed simultaneously.

Although the foregoing embodiment uses the purified water, the methanol, the isopropyl alcohol as a solvent for forming the oxide film OF, an alternative compound having the —OH functional group can be used as a solvent. For example, a compound containing at least one element selected from an alcohol group, a diol group, a carboxylic acid group, a glycol group and water, can be used as a solvent. A compound containing at least element selected from methanol, ethanol and isopropyl alcohol can be used as a solvent as well. Furthermore, a mixture of water and a compound containing at least one element selected from methanol, ethanol and isopropyl alcohol, can be used as a solvent as well.

### EXAMPLE

Hereafter examples of this invention will be described. However, this invention is by no means constrained by the examples described herein, but changes and modification can be made within the scope, which is consistent with the intent described foregoing and below and all of them are within the technical scope of this invention.

### First Example

### Oxide Film Forming by Oxide Film Forming Process

A plurality of silicon substrates with naturally oxide film adhering thereto are prepared for the oxide film to be formed by using the solvents that are different from each other with the substrate processing method described in the first embodiment. A supercritical processing condition of SCCO2 was set at 80 degrees Celsius in temperature and 20 MPa in pressure. Also, in order to confirm solvent's mixing effect with the SCCO2, following three types of processing fluid were prepared:

(A) Without solvent (processing by the only SCCO2);

(B) A processing fluid is prepared by mixing methanol only as a solvent with SCCO2; and

(C) A processing fluid is prepared by mixing methanol and purified water (5 mass %) as a solvents with SCCO2.

Oxide film forming is attempted by using each of the processing fluids. Next, increase in the oxide ingredient is measured by using XPS (X-ray photoelectron spectroscopy) on the substrates which had received the oxide film forming process with the processing fluids (A) through (C). More specifically, increase/decrease of oxide ingredient was measured based on the shape of Si2p spectrum of XPS.

The result was; while the substrate that received the oxide film forming process by using the processing fluid (A) didn't show increase in the oxide ingredient, the substrates that received the oxide film forming process by using the processing fluid (B) or the processing fluid (C) show increase in oxide ingredients.

### Second Example

### Oxide Film Forming by a Film Quality Improvement Process

A plurality of silicon substrates with naturally oxide film adhering thereto were prepared. After the naturally oxide film is removed by using diluted hydrogen fluoride (DHF) as an etchant, a chemically oxide film is formed onto each of the substrate by using ozone water. Further, the substrate processing method (film quality improvement process) described in the seventh embodiment was performed for some of the substrates with chemically oxide film formed thereon. The supercritical condition of SCCO2 was set at 80 degrees Celsius in temperature and 20 MPa in pressure. Two types of substrates was obtained: one are substrates which received the only chemically oxide film forming process (hereafter called “unimproved substrate”), the other are substrates which received both of the chemically oxide film forming process and the film quality improvement process (hereafter called “improved substrate”). Thereafter, incremental amount of oxide ingredient and sub-oxide ingredient of each substrate were measured by using XPS (X-ray photoelectron spectroscopy). More specifically, the above measurements were made based on the shape of Si2p spectrum of XPS.

Detailed comparison of the spectrum of the oxide ingredient between the unimproved substrate and the improved substrate revealed the following points. That is, it was confirmed that the amount of sub-oxide ingredient in the improved substrate decrease that in the unimproved substrate. Furthermore, amount of the stoichiometric SIO2 ingredient increases. This confirms greater film quality improvement in the improved substrate than the unimproved substrate.

Although the invention has been described with reference to specific embodiments, this description is not meant to be construed in a limiting sense. Various modifications of the disclosed embodiment, as well as other embodiments of the present invention, will become apparent to persons skilled in the art upon reference to the description of the invention. It is therefore contemplated that the appended claims will cover any such modifications or embodiments as fall within the true scope of the invention.

What is claimed is:

1. A substrate processing method, comprising the steps of:
preparing a processing fluid by means of mixing a solvent with high-pressure carbon dioxide, the solvent being a chemical compound having an —OH function group; and
forming an oxide film onto a dry surface of a substrate by means of bringing the substrate into contact with the processing fluid.

2. The substrate processing method of claim 1, further comprising the step of removing a naturally-oxide film adhering to the surface of the substrate, preceding to the oxide film forming step.

3. The substrate processing method of claim 2, wherein
the oxide film removing step is a step of bringing a processing fluid that is a mixture of high-pressure carbon dioxide and an etchant for removal of the oxide film into contact with the surface of the substrate, to thereby remove a naturally-oxide film from the surface of the substrate, and
the oxide film removing step and the oxide film forming step are performed continuously within one processing chamber.

4. The substrate processing method of claim 1, wherein
the oxide film forming step is a step of adjusting film thickness of the oxide film by means of controlling a processing condition for the oxide film forming on the surface of the substrate.

5. The substrate processing method of claim 1, further comprising the step of adjusting film thickness of the oxide film by means of removing a surface layer of the oxide film using an etching process after performing the oxide film forming step.

6. The substrate film processing method of claim 5, wherein the film thickness adjusting step is a step of supplying a processing liquid that includes an etchant for etching removal of the oxide film to the surface of the substrate, to thereby remove the surface layer of the oxide film.

7. The substrate processing method of claim 5, wherein the film thickness adjusting step is a step of bringing a processing fluid that is a mixture of an etchant for etching removal of the oxide film and high-pressure carbon dioxide into contact with the surface of the substrate, to thereby remove the surface layer of the oxide film.

8. The substrate processing method of claim 7, wherein the film thickness adjusting step and the oxide film forming step are performed continuously within one processing chamber.

9. The substrate processing method of claim 4, further comprising the step of forming a high-permittivity film on the oxide film that is adjusted the film thickness thereof.

10. The substrate processing method of claim 1, wherein the solvent includes at least one element selected from an alcohol group, a diol group, a carboxylic acid group, a glycol group and water.

11. The substrate processing method of either claim 1, wherein the solvent includes at least one element selected from methanol, ethanol and isopropyl alcohol.

12. The substrate processing method of claim 11, wherein the solvent is methanol.

13. The substrate processing method of claim 1, wherein the solvent is water.

14. The substrate processing method of claim 1, wherein the solvent is a mixture of water and a chemical compound containing at least one element selected from methanol, ethanol and isopropyl alcohol.

15. The substrate processing method of claim 14, wherein the solvent is a mixture of methanol and water.

16. A substrate processing method, comprising the steps of:
preparing a processing fluid by means of mixing a solvent with high-pressure carbon dioxide, the solvent being a chemical compound having an —OH function group; and
improving film quality of an oxide film that is formed onto a dry surface of a substrate as well as promoting incremental growth of the oxide film by means of bringing the substrate into contact with the processing fluid.

17. The substrate processing method of claim 16, wherein the oxide film that is formed onto the surface of the substrate prior to the execution of the film quality improving step is either a thermally oxide film, a vapor oxide film, a chemically oxide film or a vapor deposition film.

18. The substrate processing method of claim 16, further comprising the step of adjusting film thickness of the oxide film by means of removing a surface layer of the oxide film using an etching process after performing the film quality improving step.

19. The substrate processing method of claim 18, wherein the film thickness adjusting step is a step of supplying a processing liquid that includes an etchant for etching removal of the oxide film to the surface of the substrate, to thereby remove the surface layer of the oxide film.

20. The substrate processing method of claim 18, wherein the film thickness adjusting step is a step of bringing a processing fluid that is a mixture of an etchant for etching removal of the oxide film and high-pressure carbon dioxide into contact with the surface of the substrate, to thereby remove the surface layer of the oxide film.

21. The substrate processing method of claim 20, wherein the film thickness adjusting step and the film quality improving step are performed continuously within one processing chamber.

22. The substrate processing method of claim 18, further comprising the step of forming a high-permittivity film on the oxide film with film thickness adjusted thereto.

23. The substrate processing method of claim 18, wherein the solvent includes at least one element selected from an alcohol group, a diol group, a carboxylic acid group, a glycol group and water.

24. The substrate processing method of either claim 18, wherein the solvent includes at least one element selected from methanol, ethanol and isopropyl alcohol.

25. The substrate processing method of claim 24, wherein the solvent is methanol.

26. The substrate processing method of claim 18, wherein the solvent is water.

27. The substrate processing method of claim 18, wherein the solvent is a mixture of water and a chemical compound containing at least one element selected from methanol, ethanol and isopropyl alcohol.

28. The substrate processing method of claim 27, wherein the solvent is a mixture of methanol and water.

29. A substrate processing apparatus, comprising:
a pressure container that has a processing chamber in which a substrate having a dry surface is held; and
a processing fluid supplying unit that prepares a processing fluid by means of mixing a solvent with high-pressure carbon dioxide and supplies the same to the processing chamber, so as to form an oxide film onto the dry surface, the solvent being a chemical compound having an —OH function group.

30. A substrate processing apparatus, comprising:
a pressure container that has a processing chamber in which a substrate is held, the substrate being a dry surface onto which an oxide film is formed; and
a processing fluid supplying unit that prepares a processing fluid by mixing a solvent with high-pressure carbon dioxide and supplies the same to the processing chamber, so as to improve film quality of the oxide film as well as promote incremental growth of the oxide film, the solvent being a chemical compound having an —OH function group.
